(19) United States
(12) Patent Application Publication
(10) Pub. No.: US 2005/0008942 A1
(43) Pub. Date: Jan. 13, 2005

(54) [PHOTOMASK WITH INTERNAL ASSISTANT PATTERN FORENHANCING RESOLUTION OF MULTI-DIMENSION PATTERN]

(76) Inventors: Yung-Feng Cheng, Kaohsiung (TW); Chung-Hsien Lee, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/604,271

(22) Filed: Jul. 8, 2003

(51) Int. Cl. G03F 9/00

(52) U.S. Cl. 430/5

(57) ABSTRACT

A photomask with an internal assistant pattern, comprising a first pattern having a plurality of parallel lines along a first direction; a second pattern having a plurality of parallel lines along a second direction, wherein the second direction is different from the first direction; and an internal assistant pattern comprising a plurality of shaped structures formed in at least one of said first or second patterns, is provided. The internal assistant pattern is formed in the first pattern when the parallel lines of the second pattern are positioned along a vertical direction with respect to a common line of light exit apertures of an optical projection system. Further, the internal assistant pattern is formed in the second pattern when the parallel lines of the first pattern are positioned along a vertical direction with respect to a common line of light exit apertures of an optical projection system.

### BACKGROUND OF INVENTION

1. Filed of the Invention

The present invention relates generally to photomask used in photolithography, and more particularly to a photomask with internal assistant pattern for enhancing resolution of multi-dimension pattern.

1. Description of the Related Art

In the manufacture of a reliable semiconductor integrated circuit, it is crucial that photolithographic processes having good resolution and a large depth of focus are required to form fine patterns. As more densely packed integrated circuit designs continue to increase, a greater burden is placed on design engineers to improve upon the design of standard photomask having line patterns with very close spacing between the fine lines, places added requirements on the photolithographic processing. In addition, whether the component integration of the whole semiconductor industry can continue to advance to further reduce line width to a sub-sub-micron level will also be decided by the technological development of the photolithographic process. In order to meet this demand, processes for increasing photomask resolution, such as the process of optical proximity correction (OPC), are put forward constantly. In regions of the pattern where the spacing between the fine lines is relatively large the use of photomasks using attenuating phase shifting material produces good results. In those regions of the pattern where the spacing between the fine lines is small, however, attenuating phase shifting material will not give good results due to side lobe effect. In the case where a photomask 100 comprising a pattern 102 having parallel lines in predominantly one direction, dipole mode illumination using off axis illumination works well for reliably transferring the pattern 104 onto a layer of a photoresist 180, provided the parallel lines are positioned along a vertical direction with respect to a common line 14, of two light exit apertures 12 of a opaque panel 10 of the light projecting system, as illustrated in FIG. 1. However, in case of a photomask 200 comprising a pattern 202 where parallel lines are predominantly along a parallel direction with respect to the common line 24 of two light exit apertures of a opaque panel 20, dipole illumination mode using off axis illumination does not work well, thus the pattern 204 cannot be reliably transferred onto a layer of a photoresist 280, for example due to light scattering and/or interference effects, as illustrated in FIG. 2. Accordingly, in cases where the parallel lines are in more than one direction, for example, if the photomask comprises a plurality of patterns comprising parallel horizontal lines, and parallel vertical lines, then the pattern comprising parallel lines that are positioned predominantly along a vertical direction with respect to the common line of the dipole mode light exit apertures can be reliably transferred with expected results, whereas, for the pattern comprising parallel lines that are positioned along a parallel direction with respect to the common line of the dipole mode light exit apertures, the pattern cannot be reliably transferred due to, for example, light scattering and/or interference effects. In order to reliably transfer the above pattern on to a photoresist layer, substantially two separate photomasks with one having the parallel horizontal lines, and the second photomask having the parallel vertical lines, and further, two separate exposure steps are required for accomplishing the formation of the above patterns onto a layer of a photoresist, wherein the first exposure is performed by positioning the dipole mode light exit apertures substantially along a direction parallel to the horizontal parallel lines and the second exposure step is performed by positioning the dipole mode light exit apertures substantially along a direction parallel to the vertical parallel lines. Further, two or more exposure steps could cause defects due overlay problems, which could be of reliability concern. Besides, fabrication cost is substantially increased due to use of an increased number photomasks.

### SUMMARY OF INVENTION

Accordingly, in the light of the foregoing, it is an object of the present invention to provide a new photomask with an internal assistant pattern, which photomask is capable of enhancing the resolution of multi-dimensional pattern so that patterns having parallel lines in more than one direction can be reliably transferred onto a layer of a photoresist by using a single photomask through a single exposure step. This not only allows the reduction in the number of photomasks in the fabrication of the semiconductor processing but also substantially promotes the reliability of the semiconductor device.

According to one aspect of the present invention, a photomask with an internal assistant pattern, comprising at least a pattern having a plurality of parallel lines is provided.

According to another aspect of the present invention, a photomask with an internal assistant pattern, comprising a first pattern having a plurality of parallel lines along a first direction; a second pattern having a plurality of parallel lines along a second direction, wherein the second direction is different from the first direction; and an internal assistant pattern comprising a plurality of shaped structures formed in at least one of said first or second patterns, is provided. The internal assistant pattern is formed in the first pattern when the parallel lines of the second pattern is positioned parallel with respect to a direction of a common line of light exit apertures of an optical projection system. Further, the internal assistant pattern is formed in the second pattern when the parallel lines of the first pattern is positioned along a vertical direction with respect to a direction of a common line of light exit apertures of an optical projection system.

According to another aspect of the present invention, a photomask with an internal assistant pattern, comprising a horizontal pattern having a plurality of horizontal parallel lines; a vertical pattern having a plurality of vertical parallel lines; and an internal assistant pattern comprising a plurality of shaped structures in at least one of said horizontal or vertical patterns, is provided. The internal assistant pattern is formed in the horizontal pattern when the parallel lines of the vertical pattern are positioned along a vertical direction with respect to a direction of a common line 24 of light exit apertures of an optical projection system. Further, the internal assistant pattern is formed in the vertical pattern when the parallel lines of the horizontal pattern are positioned along a parallel direction with respect to a direction of a common line 24 of light exit apertures of an optical projection system.

According to an aspect of the present invention, the photomask of the present invention is exposed using off axis illumination mode, preferably a dipole illumination mode for forming the pattern on a layer of a photoresist that is disposed on the semiconductor substrate.

The term “common line of light exit apertures of an optical projection system” mentioned above refers to an imaginary line which passes through the centers of the two light exit apertures of a light projection system in a dipole illumination mode.

It is to be understood that by including an internal assistant pattern within a pattern, phenomenon of critical dimension (CD) bias caused by proximity effect can be effectively eliminated to effective promote the optical resolution of the pattern.

### BRIEF DESCRIPTION OF DRAWINGS

For a more complete understanding of the present invention, reference will now be made to the following detailed description of preferred embodiments taken in conjunction with the accompanying drawings.

FIG. 1 illustrates the effect of a dipole illumination mode for forming a parallel lines pattern with parallel lines positioned along a vertical direction with respect to a common line of two light exit apertures of a light projecting system.

FIG. 2 illustrates the effect of a dipole illumination mode for forming a parallel lines pattern with parallel lines positioned along a parallel direction with respect to a common line of two light exit apertures of a light projecting system.

FIG. 3 illustrates the effect of a photomask with an internal assistant pattern using a dipole illumination mode according to a preferred embodiment of the present invention.

FIG. 4 illustrates the effect of a photomask with an internal assistant pattern using a dipole illumination mode according to another preferred embodiment of the present invention.

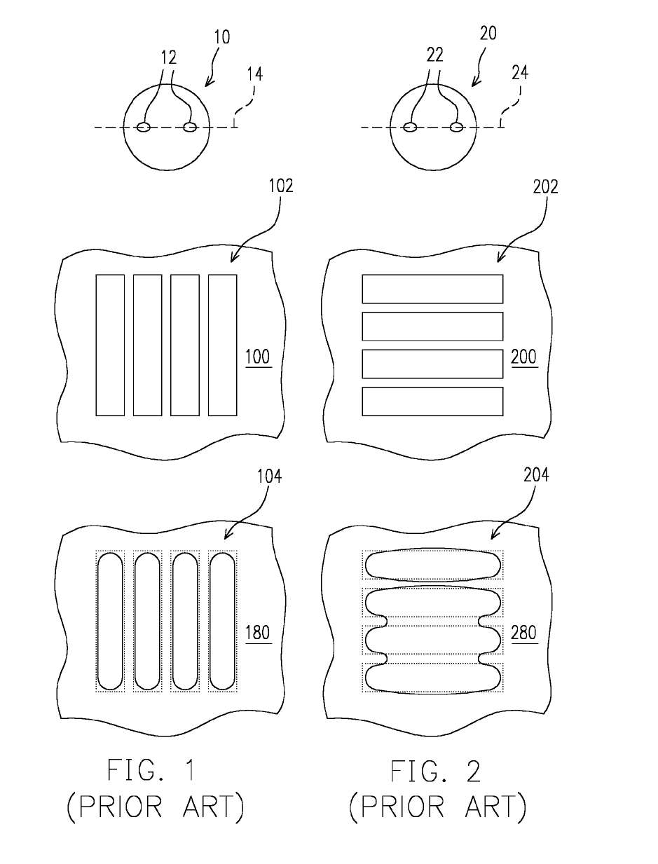

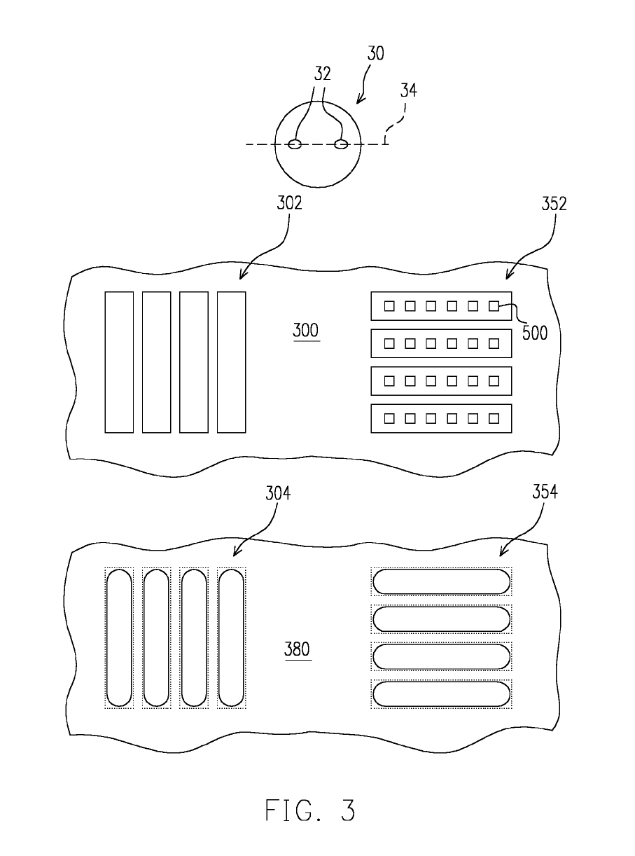

### DETAILED DESCRIPTION

Reference will be made in detail to the present preferred embodiments of the invention, examples of which are illustrated in the accompanying drawings. Wherever possible, the same reference numbers are used in the drawings and the description to refer to the same or like parts.

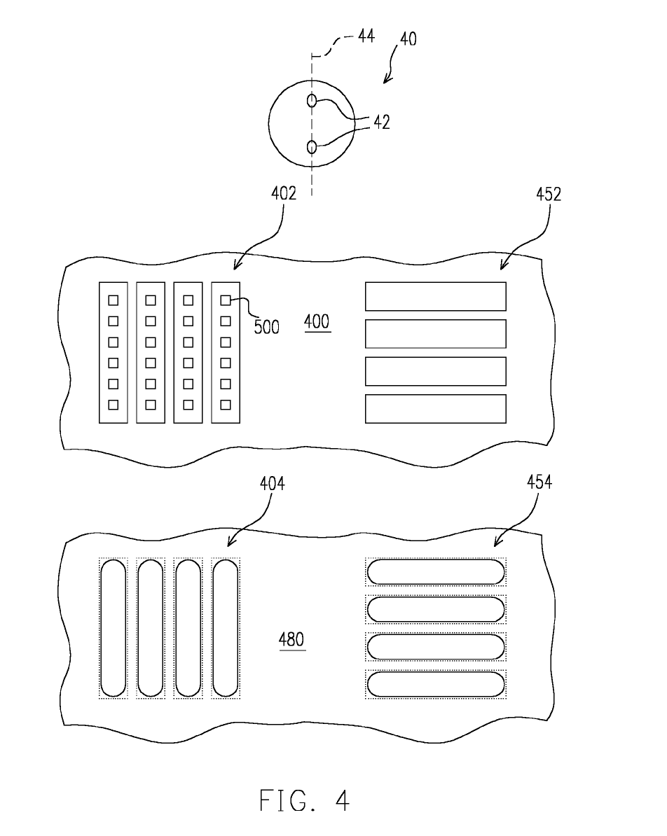

Referring to FIGS. 3-4, description of the preferred embodiments using the photomask of the present invention for exposing a layer of photoresist on an integrated circuit wafer for reliably transferring a multi-dimensional pattern is described as follows.

FIG. 3 illustrates improvement of resolution using the photomask with an internal assistant pattern using a dipole mode off axis illumination according to one preferred embodiment of the present invention. As shown in FIG. 3, a top view of a structure of an opaque panel 30 of in a light projecting system, comprising two light exit apertures 32 positioned along a common line 34; a top view of a segment of a photomask 300 comprising a plurality of patterns 302 and 352. The pattern 302 comprises a plurality of parallel lines extending along a vertical direction with respect to the common line 34, and the pattern 352 comprises a plurality of parallel lines extending along a direction parallel with respect to the common line 34. An internal assistant pattern 500 of the present invention is included within the pattern 352.

The internal assistant pattern 500 of the present invention constitutes shaped through holes when the pattern is to be transferred onto layer of a negative photoresist (380), and the internal assistant pattern 500 constitute shaped opaque structures when the pattern is to be transferred onto a layer of positive photoresist (380). The shape of the internal assistant pattern 500 is comprised of, but not limited to, a square, a rectangle, or a circle.

When the photomask 300 of the present is exposed through the light exit apertures 32, since the parallel lines of the pattern 302 are positioned along a vertical direction with respect to the common line 34 of the light exit apertures 32, therefore, the pattern 302 can be reliably transferred as a pattern 304 onto a layer of a photoresist 380 as shown in FIG. 3. Further, even though the parallel lines of the pattern 352 are positioned along a parallel direction with respect to the common line 34, because the internal assistant pattern 500 is disposed within the pattern 352, the phenomenon of critical dimension (CD) bias caused by proximity effect due to, for example, light scattering and/or interference effects, can be effectively reduced or eliminated. Thus the optical resolution can be effectively enhanced. Accordingly, the pattern 352 can be reliably transferred as pattern 354 onto the layer of the photoresist 380 as shown in FIG. 3.

FIG. 4 illustrates the effect of the photomask 400 with internal assistant pattern 500 of the present invention comprising a plurality of patterns 402 and 452 according to another preferred embodiment of the present invention. The principle of the present invention remains the same as described taking FIG. 3 as an example except that the opaque panel 40 of the light projection system is rotated by 90° and that the internal assistant pattern 500 is disposed within pattern 402, wherein the parallel lines of pattern 402 are positioned along a parallel direction with respect to a common line 44 of the light exit apertures 42, as shown in FIG. 4. Accordingly, patterns 402 and 452 are reliably transferred as patterns 404 and 454 respectively onto a layer of a photoresist 480.

Even though the present invention is described using a photomask comprising two patterns, with one pattern having parallel lines substantially extending along a vertical direction with respect to the parallel line of the second pattern, however, it is to be understood that more than two patterns may be formed on the same photomask, and that the direction parallel lines can be at any angle with respect to the common line of the two light exit apertures, and that most importantly though that the internal assistant features is included within those patterns comprising parallel lines that extend substantially in a direction different compared to the common line of the two light exit apertures, in order to practice the present invention. Thus, this makes it possible to form a plurality patterns with parallel lines extending in more than one direction on the same photomask so that a multi-dimensional pattern can be reliably transferred onto a layer of a photoresist by using a single photomask through a single exposure step. Thus, the number of photomask in a semiconductor processing can be effectively reduced so that the processing cost can be effectively reduced. Further, this would substantially reduce defects, for example, overlay defects, due to multiple exposures.

It is to be further understood that if the photomask comprises a single pattern, the internal assistant pattern might be used to improve the optical resolution of the pattern.

Even though the present invention is described taking pattern having parallel lines, however, it is to be understood that the principle of the present invention can also be applied to other types of patterns.

While the invention has been described in conjunction with a specific best mode, it is to be understood that many alternatives, modifications, and variations will be apparent to those skilled in the art in light of the a foregoing description. Accordingly, it is intended to embrace all such alternatives, modifications, and variations, which fall within the spirit and scope of the included claims. All matters set forth herein or shown in the accompanying drawings are to be interpreted in an illustrative and nonlimiting sense.

1. A photomask with an internal assistant pattern, comprising:
at least a pattern comprising a plurality of parallel lines; and
an internal assistant pattern comprising a shaped structure formed in said pattern.

2. The photomask of claim 1, wherein the shape of the shaped structure of the internal assistant pattern is one selected from a group consisting, a square, a rectangle, and a circle.

3. A photomask with an internal assistant pattern, comprising:
an opaque panel comprising two light exit apertures, for exposing the photomask, wherein the two light exit apertures are positioned along a common line;
a first pattern comprising a plurality of parallel lines along a first direction;
a second pattern comprising a plurality of parallel lines along a second direction, wherein the second direction is different from the first direction, wherein at least parallel lines of said first or second pattern is positioned parallel to said common line; and
an internal assistant pattern comprising a shaped structure formed in one of said firs or second patterns.

4. The photomask of claim 3, wherein the internal assistant pattern is formed in the first pattern when the parallel lines of the second pattern are positioned along a vertical direction with respect to the common line of two light exit apertures.

5. The photomask of claim 3, wherein the internal assistant pattern is formed in the second pattern when the parallel lines of the first pattern is positioned along a vertical direction with respect to the common line of two light exit apertures.

6. The photomask of claim 3, wherein the shape of the shaped structure of the internal assistant pattern is one selected from a group consisting, a square, a rectangle, and a circle.

7. A photomask with an internal assistant pattern, comprising:
an opaque panel comprising two light exit apertures, for exposing the photomask, wherein the two light exit apertures are positioned along a common line;
a horizontal pattern comprising a plurality of parallel lines;
a vertical pattern comprising a plurality of parallel lines; and
an internal assistant pattern comprising a shaped structure in at least one of said horizontal or vertical patterns.

8. The photomask of claim 7, wherein the internal assistant pattern is formed in the horizontal pattern when the parallel lines of the vertical pattern are positioned along a vertical direction with respect to the common line of two light exit apertures.

9. The photomask of claim 7, wherein the internal assistant pattern is formed in the vertical pattern when the parallel lines of the horizontal pattern are positioned along a vertical direction with respect to the common line of two light exit apertures.

10. The photomask of claim 7, wherein the shape of the shaped structure of the internal assistant pattern is one selected from a group consisting, a square, a rectangle, and a circle.
